(19) United States
(12) Patent Application Publication
(10) Pub. No.: US 2026/0231698 A1
(43) Pub. Date: Aug. 6, 2026

(54) SEMICONDUCTOR MATERIAL AND METHOD FOR PREPARING THE SAME

(71) Applicant: NATIONAL TSING HUA UNIVERSITY, HSINCHU (TW)

(72) Inventors: Chao-Hui YEH, Yunlin County (TW); Ying-Hao CHU, Kaohsiung City (TW); Po-Wen CHIU, HSINCHU (TW)

(21) Appl. No.: 19/531,678

(22) Filed: Feb. 6, 2026

Related U.S. Application Data
(60) Provisional application No. 63/755,230, filed on Feb. 6, 2025.

(51) Int. Cl. H10P 14/20; H10P 14/40

(52) U.S. Cl. CPC H10P 14/3436; H10P 14/272; H10P 14/3438; H10P 14/40

(57) ABSTRACT

A method for preparing a semiconductor material includes the steps as follows. A first chalcogenide material is ablated by a power source at a first frequency to form a plurality of first chalcogenide units. The first chalcogenide units are deposited on a substrate to form a base layer. At least one masking layer is formed on the base layer. A second chalcogenide material is ablated by the power source at a second frequency to form a plurality of second chalcogenide units. The second chalcogenide units are deposited on the portion of the surface of the base layer to form at least one doping area. The at least one masking layer is removed to obtain the semiconductor material.

### RELATED APPLICATIONS

This application claims priority to US Provisional Application Serial Number 63/755,230, filed February 06, 2025, which is herein incorporated by reference.

### BACKGROUND

### Technical Field

The present disclosure relates to a material and a method for preparing the material. More particularly, the present disclosure relates to a semiconductor material and a method for preparing the semiconductor material.

### Description of Related Art

Modulating the carrier concentration in a semiconductor material via the doping method is the most common method for preparing the semiconductor material so as to adjust the electrical properties and the performance of the semiconductor material. The conventional doping method is the ion implantation method, in which the doping material is ionized and the kinetic energy of the ionized doping material is promoted, the ion movement is accelerated and the direction of the ion movement is controlled by an electric field, and the ionized doping material is implanted in a chip, so that the doping material diffuses into the chip to complete the doping process of the semiconductor material.

In the conventional doping method, the kinetic energy and the moving direction of the ionized doping material cannot be precisely controlled after entering the semiconductor material, so that the ions of the doping material would ruin the crystal structure of the semiconductor material, and influence the performance stability of the semiconductor material. Moreover, the location of the doping area of the semiconductor material cannot be precisely controlled, which influence the production yield rate of the semiconductor material. Thus, the electrical properties and the performance stability of the semiconductor material is a major challenge in the doping process without an effective control.

Therefore, developing a method for preparing a semiconductor material, which can precisely control the doping process and would not ruin the crystal structure of the semiconductor material so as to prepare the semiconductor material with a high performance and a precise dimension has been the main goal of the industry.

### SUMMARY

According to one aspect of the present disclosure, a method for preparing a semiconductor material includes the steps as follows. A first chalcogenide material is ablated by a power source at a first frequency to form a plurality of first chalcogenide units. The first chalcogenide units are deposited on a substrate to form a base layer. At least one masking layer is formed on the base layer, wherein a portion of a surface of the base layer is exposed outside the at least one masking layer. A second chalcogenide material is ablated by the power source at a second frequency to form a plurality of second chalcogenide units. The second chalcogenide units are deposited on the portion of the surface of the base layer to form at least one doping area. The at least one masking layer is removed to obtain the semiconductor material.

According to another aspect of the present disclosure, a semiconductor material is prepared by the method for preparing the semiconductor material of the aforementioned aspect, and includes the base layer and the at least one doping area. The base layer includes the first chalcogenide units, the at least one doping area includes the second chalcogenide units, and the second chalcogenide units are bonded to the first chalcogenide units of the base layer.

### BRIEF DESCRIPTION OF THE DRAWINGS

The present disclosure can be more fully understood by reading the following detailed description of the embodiment, with reference made to the accompanying drawings as follows:

FIG. 1 is a flow chart of a method for preparing a semiconductor material according to one embodiment of the present disclosure.

FIG. 2 is a schematic view of a laser ablating device used in the method for preparing the semiconductor material in FIG. 1.

FIG. 3A is a cross-sectional view of a substrate and a base layer in the method for preparing the semiconductor material in FIG. 1.

FIG. 3B is a cross-sectional view of a masking layer and a doping area in the method for preparing the semiconductor material in FIG. 1.

FIG. 3C is a cross-sectional view of an electrode structure.

FIG. 3D is a cross-sectional view of the semiconductor material in the method for preparing the semiconductor material in FIG. 1.

FIG. 4A is a structural schematic view of a semiconductor material according to another embodiment of the present disclosure.

FIG. 4B is a structural schematic view of a semiconductor material according to still another embodiment of the present disclosure.

FIG. 4C is a structural schematic view of a semiconductor material according to yet another embodiment of the present disclosure.

FIG. 5 is a scanning electron microscope image of Example 1.

FIG. 6A is an I_{D}-V_{D} diagram of Comparative example 1.

FIG. 6B is an I_{D}-V_{D} diagram of Example 1.

FIG. 7 is an I_{D}-V_{G} diagram of Example 1 and Comparative example 1.

FIG. 8 is an I_{D}-V_{G} diagram of Example 2 and Example 3.

FIG. 9A is a hysteresis analysis of Comparative example 1.

FIG. 9B is a hysteresis analysis of Example 1.

### DETAILED DESCRIPTION

The present disclosure will be further exemplified by the following specific embodiments. However, the embodiments can be applied to various inventive concepts and can be embodied in various specific ways. The specific embodiments are only for the purposes of description, and are not limited to these practical details thereof. In addition, some conventional structures and elements are illustrated in the drawings in a simple and schematic way, and repeated elements can be presented by the same or similar reference numerals.

### Method for Preparing Semiconductor Material

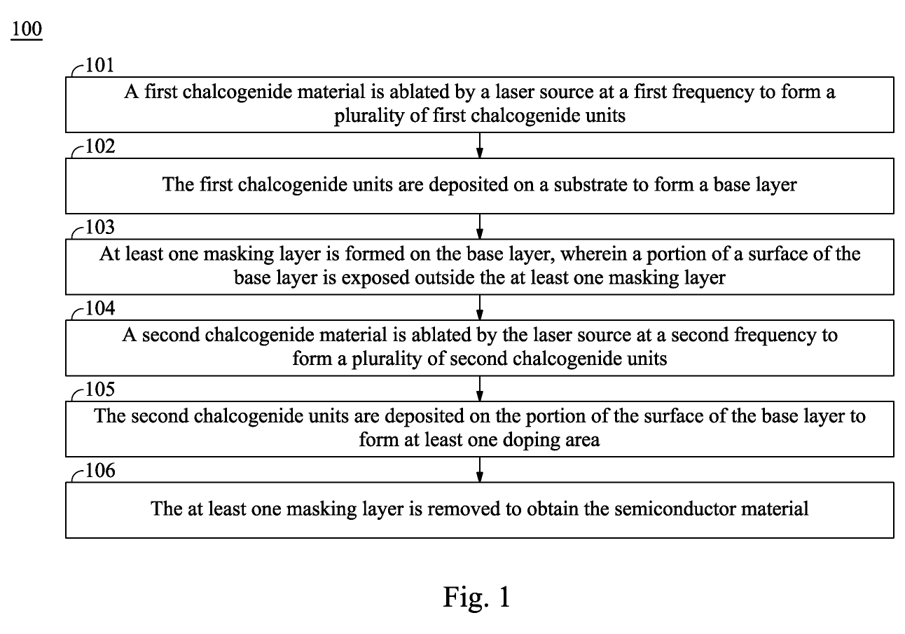

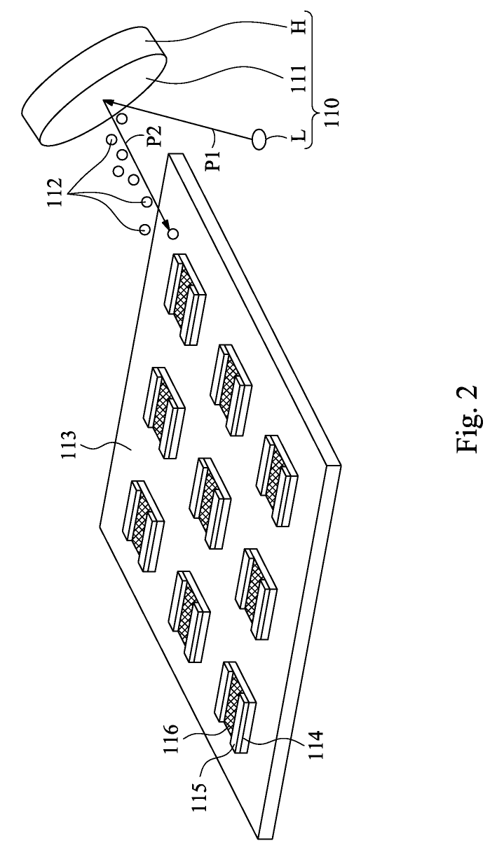

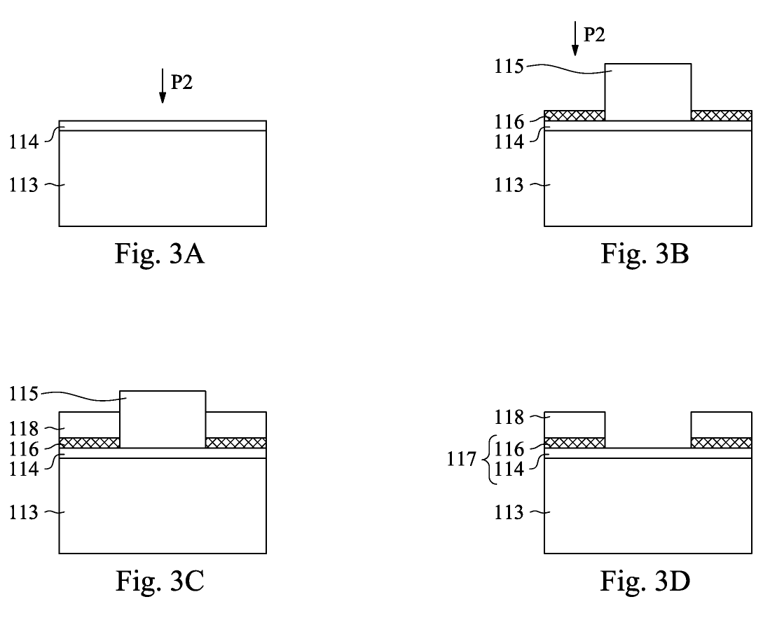

Reference is made to FIG. 1 to FIG. 3D, FIG. 1 is a flow chart of a method for preparing a semiconductor material 100 according to one embodiment of the present disclosure, FIG. 2 is a schematic view of a laser ablating device 110 used in the method for preparing the semiconductor material 100 in FIG. 1, FIG. 3A is a cross-sectional view of a substrate 113 and a base layer 114 in the method for preparing the semiconductor material 100 in FIG. 1, FIG. 3B is a cross-sectional view of a masking layer 115 and a doping area 116 in the method for preparing the semiconductor material 100 in FIG. 1, FIG. 3C is a cross-sectional view of an electrode structure 118, FIG. 3D is a cross-sectional view of the semiconductor material 117 in the method for preparing the semiconductor material 100 in FIG. 1. In FIG. 1, the method for preparing the semiconductor material 100 includes step 101, step 102, step 103, step 104, step 105 and step 106.

In step 101, a first chalcogenide material (not shown) is ablated by a power source L at a first frequency to form a plurality of first chalcogenide units (not shown). In FIG. 2, the laser ablating device 110 includes the power source L, a fixing holder H and a chalcogenide material 111. The working procedure of the laser ablating device 110 includes the steps as follows. The chalcogenide material 111 is disposed in the fixing holder H. The chalcogenide material 111 is ablated by the power source L along a path P1 towards a surface of the chalcogenide material 111 to form a plurality of chalcogenide units 112. It should be noted that the chalcogenide material 111 in the fixing holder H can be configured as a first chalcogenide material or a second chalcogenide material according to the needs in different steps. Specifically, in step 101, the first chalcogenide material is disposed in the fixing holder H, and the first chalcogenide material is ablated by the power source L to form the first chalcogenide units, but is not limited thereto. Furthermore, the power source L can be a laser source, and a wavelength of the laser source can be 100 nm to 850 nm. Therefore, the ablating performance of the power source L can be ensured so as to uniform the size of the first chalcogenide units, and it is beneficial for the precise dimension of the semiconductor material 117. Further, the first frequency can be 0.1 Hz to 1000 Hz. Therefore, the generating efficiency of the first chalcogenide units can be ensured. Preferably, the first frequency can be 0.1 Hz to 500 Hz. Therefore, the physical stability of the first chalcogenide units can be ensured. More preferably, the first frequency can be 0.1 Hz to 100 Hz. Therefore, the structural integrity of the first chalcogenide units can be ensured.

In step 102, the first chalcogenide units are deposited on the substrate 113 to form the base layer 114. In FIG. 2 and FIG. 3A, when the chalcogenide units 112 are the first chalcogenide units, the first chalcogenide units are deposited through a path P2 on the substrate 113 to form the base layer 114. Moreover, a material of the substrate 113 can be glass, silicon, silicon dioxide, polyimide, graphite, metal oxide or ceramic. The material of the substrate 113 can be selected based on the requirement so as to extend the applicability of the semiconductor material 117. Furthermore, a thickness of the substrate 113 can be 30 nm to 200 nm. Therefore, the production yield rate of the method for preparing the semiconductor material 100 can be improved.

In step 103, the at least one masking layer 115 is formed on the base layer 114, wherein a portion of a surface of the base layer 114 is exposed outside the at least one masking layer 115. Moreover, the masking layer 115 can include a resin and a photosensitizer, but not limited thereto. Therefore, the operation procedure of the method for preparing the semiconductor material 100 can be simplified and the process stability can be improved.

In step 104, a second chalcogenide material (not shown) is ablated by the power source L at a second frequency to form a plurality of second chalcogenide units (not shown). In FIG. 2, in step 104, the second chalcogenide material is disposed in the fixing holder H, and the second chalcogenide material is ablated by the power source L to form the second chalcogenide units, but note limited thereto. Furthermore, the power source L can be a laser source, and the wavelength of the laser source can be 100 nm to 850 nm. Therefore, the ablating performance of the power source L can be ensured so as to uniform the size of the second chalcogenide units, and it is beneficial for the precise dimension of the semiconductor material 117. Further, the second frequency can be 0.1 Hz to 1000 Hz. Therefore, the generating efficiency of the second chalcogenide units can be ensured. Preferably, the second frequency can be 0.1 Hz to 500 Hz. Therefore, the physical stability of the second chalcogenide units can be ensured. More preferably, the second frequency can be 0.1 Hz to 100 Hz. Therefore, the structural integrity of the second chalcogenide units can be ensured. In detail, the power source L can include at least one selected from the group consisting of a laser source, a charged-particle source, a neutral-particle source and a broadband photon source, and wherein one or more operating parameter of the power source are configurable to deliver energy. Moreover, the power source L can be a pulsed laser or a continuous-wave laser. As the power source L is the pulsed laser, and a repetition rate of the pulsed laser can be 0.01 Hz to 100 MHz. Therefore, it is favorable for the controllability of the power source L, and the structure of the semiconductor material 117 can be controlled by adjusting operating parameters of the power source L.

In step 105, the second chalcogenide units are deposited on the portion of the surface of the base layer 114 to form at least one doping area 116. In FIG. 2 and FIG. 3B, when the chalcogenide units 112 are the second chalcogenide units, the second chalcogenide units are deposited through the path P2 on the base layer 114 to form the doping area 116. Therefore, the electrical properties of the semiconductor material 117 can be precisely adjusted. Further, a heating temperature provided on the portion of the surface of the base layer 114 can be 200^{o}C to 330^{o}C during depositing the second chalcogenide units on the portion of the surface of the base layer 114. Therefore, the depositing efficiency can be improved. Preferably, the heating temperature can be 250^{o}C to 300^{o}C. Therefore, the depositing efficiency can be improved, and the uniformity of the doping area 116 can be ensured, and it is favorable for the quality of the semiconductor material 117.

In step 106, the at least one masking layer 115 is removed to obtain the semiconductor material 117. In detail, at least one electrode structure 118 is formed on the at least one doping area 116 before removing the at least one masking layer 115. In FIG. 3C and FIG. 3D, the electrode structure 118 corresponds to the doping area 116, the semiconductor material 117 can be electrically connected to mating elements via the electrode structure 118, so that the applicability variety of the semiconductor material 117 can be increased. Specifically, the electrode structure 118 can include palladium and gold. Therefore, it is favorable for the durability of the electrode structure 118.

Moreover, a chalcogenide source of the first chalcogenide material can be sulfur, selenium or tellurium, and a chalcogenide source of the second chalcogenide material can be sulfur, selenium or tellurium. In detail, all sulfur, selenium or tellurium are chalcogen, which forms chalcogenide materials having unique electrical properties, and it is favorable for the applicability of the semiconductor material 117. Applying the semiconductor material 117 to electronic components can increase the transmission speed and electrical performance of the electronic components. Furthermore, the first chalcogenide material can include a group IIIB element, a group IVB element, a group VB element, a group VIB element, a group VIIB element, a group VIIIB element, a group IB element, a group IIB element or a group VA element of Periodic Table. Therefore, it is favorable for flexibly adjusting the characteristics of the semiconductor material 117. Preferably, the first chalcogenide material can include the group VB element, the group VIB element or the group VA element of Periodic Table. Therefore, it is favorable for the bonding stability of the semiconductor material 117.

In detail, the second chalcogenide material can include a group IIIB element, a group IVB element, a group VB element, a group VIB element, a group VIIB element, a group VIIIB element, a group IB element, a group IIB element or a group VA element of Periodic Table. Therefore, it is favorable for flexibly adjusting the characteristics of the semiconductor material 117. Preferably, the second chalcogenide material can include the group VB element, the group VIB element or the group VA element of Periodic Table. Therefore, it is favorable for the bonding stability of the semiconductor material 117.

Further, a plurality of third chalcogenide units (not shown) can be further deposited on the semiconductor material 117, each of the third chalcogenide units can include a third chalcogenide material, and the third chalcogenide units are bonded to the first chalcogenide units on the semiconductor material 117, so that the semiconductor material 117 can include at least one p-type semiconductor portion and at least one n-type semiconductor portion. Therefore, the characteristics of the semiconductor material 117 can be controlled by arranging of the at least one p-type semiconductor portion and the at least one n-type semiconductor portion.

### Semiconductor Material

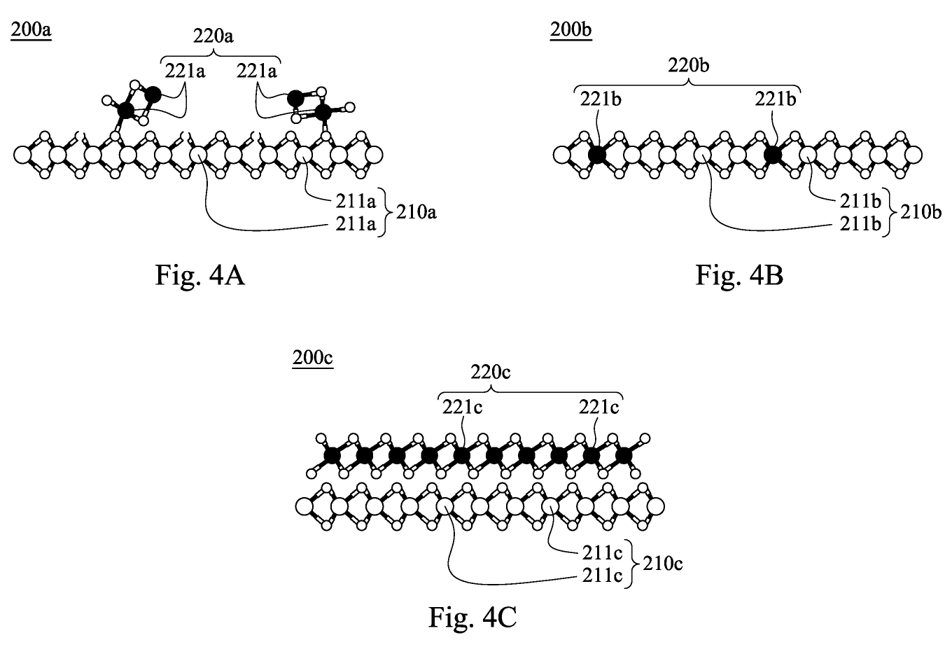

Reference is made to FIG. 4A to FIG. 4C, FIG. 4A is a structural schematic view of a semiconductor material 200a according to another embodiment of the present disclosure, FIG. 4B is a structural schematic view of a semiconductor material 200b according to still another embodiment of the present disclosure, FIG. 4C is a structural schematic view of a semiconductor material 200c according to yet another embodiment of the present disclosure. The semiconductor materials 200a, 200b, 200c are prepared by the method for preparing the semiconductor material of the present disclosure. In FIG. 4A, the semiconductor material 200a includes the base layer 210a and the at least one doping area 220a. The base layer 210a includes first chalcogenide units 211a. The at least one doping area 220a includes second chalcogenide units 221a, and the second chalcogenide units 221a are bonded to the first chalcogenide units 211a of the base layer 210a. In detail, the doping area 220a covers a portion of the base layer 210a so as to form the two-dimensional structure of the semiconductor material 200a. Specifically, the semiconductor material 200a is formed as the heating temperature is low, wherein the doping area 220a is bonded to the surface of the base layer 210a, and no atom substitution occurs. In FIG. 4B, the semiconductor material 200b includes a base layer 210b and at least one doping area 220b. The base layer 210b includes first chalcogenide units 211b. The at least one doping area 220b includes second chalcogenide units 221b, and the second chalcogenide units 221b are bonded to the first chalcogenide units 211b of the base layer 210b. In detail, the second chalcogenide units 221b can fill the structural defect of the base layer 210b, so as to reduce the structural defect in the semiconductor material 200b, and to improve the electrical properties and the reactivity of the semiconductor material 200b. Specifically, the semiconductor material 200b is formed as the heating temperature is high, wherein the doping area 220b has sufficient kinetic energy to penetrate into the base layer 210b, and the atom substitution occurs. In FIG. 4C, the semiconductor material 200c includes a base layer 210c and at least one doping area 220c. The base layer 210c includes first chalcogenide units 211c. The at least one doping area 220c includes second chalcogenide units 221c, and a Van der Waals force exists between the second chalcogenide units 221c and the first chalcogenide units 211c of the base layer 210c. In detail, the second chalcogenide units 221c cover a surface of the base layer 210c to form the semiconductor material 200c with a multi-layer structure. Specifically, the semiconductor material 200c is formed as the heating temperature is low, and the complete doping area 220c is formed on the surface of the base layer 210c by adjusting the second frequency of the power source. Therefore, the structures and the electrical properties of the semiconductor materials 200a, 200b, 200c can be adjusted by adjusting the wavelength, the first frequency and the second frequency of the power source.

Specifically, the first chalcogenide material can include a group VIB element of Periodic Table, the second chalcogenide material can include a group IIIB element, a group IVB element or a group VB element of Periodic Table, and the semiconductor material 200a, 200b, 200c can include at least one p-type semiconductor portion. Therefore, it is favorable for flexibly adjusting the characteristics of the semiconductor material 200a, 200b, 200c. Preferably, the first chalcogenide material can include the group VIB element of Periodic Table, the second chalcogenide material can include the group VB element of Periodic Table, and the semiconductor material 200a, 200b, 200c can include the at least one p-type semiconductor portion. Therefore, it is favorable for the bonding stability of the semiconductor material 200a, 200b, 200c.

Alternately, the first chalcogenide material can include a group VIB element of Periodic Table, the second chalcogenide material can include a group VIIB element, a group VIIIB element, a group IB element, a group IIB element or a group VA element of Periodic Table, and the semiconductor material 200a, 200b, 200c can include at least one n-type semiconductor portion. Therefore, it is favorable for flexibly adjusting the characteristics of the semiconductor material 200a, 200b, 200c. Preferably, the first chalcogenide material can include the group VIB element of Periodic Table, the second chalcogenide material can include the group VA element of Periodic Table, and the semiconductor material 200a, 200b, 200c can include the at least one n-type semiconductor portion. Therefore, it is favorable for the bonding stability of the semiconductor material 200a, 200b, 200c.

Moreover, the first chalcogenide material can include a group VB element of Periodic Table, the second chalcogenide material can include a group IIIB element or a group IVB element of Periodic Table, and the semiconductor material 200a, 200b, 200c can include the at least one p-type semiconductor portion. The first chalcogenide material can include a group VB element of Periodic Table, the second chalcogenide material can include a group VIB element, a group VIIB element, a group VIIIB element, a group IB element, a group IIB element or a group VA element of Periodic Table, and the semiconductor material 200a, 200b, 200c can include the at least one n-type semiconductor portion. Therefore, it is favorable for flexibly adjusting the characteristics of the semiconductor material 200a, 200b, 200c.

Furthermore, the semiconductor material 200a, 200b, 200c can further include at least one covering layer (not shown) covering the base layer 210a, 210b, 210c, the at least one covering layer can include a plurality of third chalcogenide units, each of the third chalcogenide units can include a third chalcogenide material, and the third chalcogenide units are bonded to the first chalcogenide units 211a, 211b, 211c of the base layer 210a, 210b, 210c.

In detail, the first chalcogenide material can include a group VIB element of Periodic Table, the second chalcogenide material can include a group IIIB element, a group IVB element or a group VB element of Periodic Table, the third chalcogenide material can include a group VIIB element, a group VIIIB element, a group IB element, a group IIB element or a group VA element of Periodic Table, and the semiconductor material 200a, 200b, 200c can include at least one p-type semiconductor portion and at least one n-type semiconductor portion. Therefore, the characteristics of the semiconductor material 200a, 200b, 200c can be controlled by arranging of the at least one p-type semiconductor portion and the at least one n-type semiconductor portion.

Alternately, the first chalcogenide material can include a group VB element of Periodic Table, the second chalcogenide material can include a group IIIB element or a group IVB element of Periodic Table, the third chalcogenide material can include a group VIB element, a group VIIB element, a group VIIIB element, a group IB element, a group IIB element or a group VA element of Periodic Table, and the semiconductor material 200a, 200b, 200c can include at least one p-type semiconductor portion and at least one n-type semiconductor portion. Therefore, the characteristics of the semiconductor material 200a, 200b, 200c can be controlled by arranging of the at least one p-type semiconductor portion and the at least one n-type semiconductor portion.

The following specific examples further illustrate the present disclosure for those with ordinary skill in the technical field to utilize and realize the present disclosure without excessive interpretation. These examples should not limit the scope of the present disclosure, but illustrate how to implement the materials and methods of the present disclosure.

### Example/Comparative example

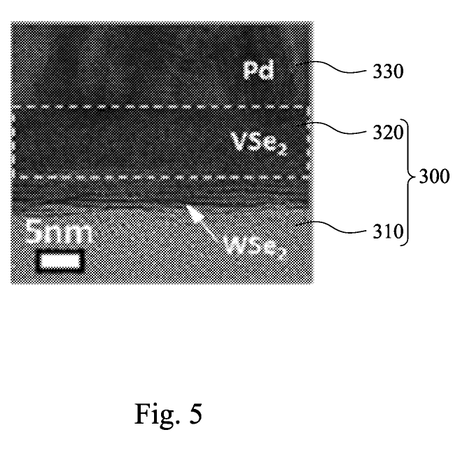

Example 1: the semiconductor material of Example 1 (hereinafter referred to as Example 1) was prepared by the method for preparing the semiconductor material of the present disclosure, wherein the wavelength of the power source was 100 nm to 850 nm, the first frequency was 0.1 Hz to 1000 Hz, and the second frequency was 0.1 Hz to 1000 Hz. Moreover, the heating temperature was 200^{o}C to 330^{o}C, the material of the substrate is silicon dioxide. The base layer 310 of Example 1 includes a first chalcogenide material, and the first chalcogenide material is tungsten diselenide. The doping area 320 of Example 1 includes a second chalcogenide material, and the second chalcogenide material is vanadium diselenide. Furthermore, the electrode structure 330 was formed on the doping area 320, and the electrode structure 330 includes palladium. Reference is made to FIG. 5, which is a scanning electron microscope image of Example 1. In FIG. 5, Example 1 includes tungsten diselenide of the base layer 310 and vanadium diselenide of the doping area 320. It can be demonstrated that the semiconductor material 300 can be successfully prepared by the method for preparing the semiconductor material of the present disclosure.

Example 2: the semiconductor material of Example 2 (hereinafter referred to as Example 2) was prepared by the method for preparing the semiconductor material similar to the method for preparing Example 1, and the difference is that the first chalcogenide material and the second chalcogenide material for preparing Example 2 are different from Example 1. The base layer of Example 2 includes a first chalcogenide material, and the first chalcogenide material is tungsten diselenide with vanadium diselenide doping. The doping area of Example 2 includes a second chalcogenide material, and the second chalcogenide material is vanadium diselenide.

Example 3: the semiconductor material of Example 3 (hereinafter referred to as Example 3) was prepared by the method for preparing the semiconductor material similar to the method for preparing Example 1, and the difference is that the first chalcogenide material and the second chalcogenide material for preparing Example 3 are different from Example 1. The base layer of Example 3 includes a first chalcogenide material, and the first chalcogenide material is tungsten diselenide. The doping area of Example 3 includes a second chalcogenide material, and the second chalcogenide material is bismuth(II) selenide.

Comparative example 1: the semiconductor material of Comparative example 1 (hereinafter referred to as Comparative example 1) is tungsten diselenide.

### Field Effect Analysis

The field effect analysis includes I_{D}-V_{D} analysis and I_{D}-V_{G} analysis. In detail, the semiconductor material is applied as a field-effect transistor (FET), and the MOSET can be turned on by applying the applying voltage V_{G}. When the applying voltage V_{G} exceeds the threshold voltage Vₜₕ, the FET is turned on. Different drain currents I_{D} can be generated by providing voltage V_{D} at different V_{G}.

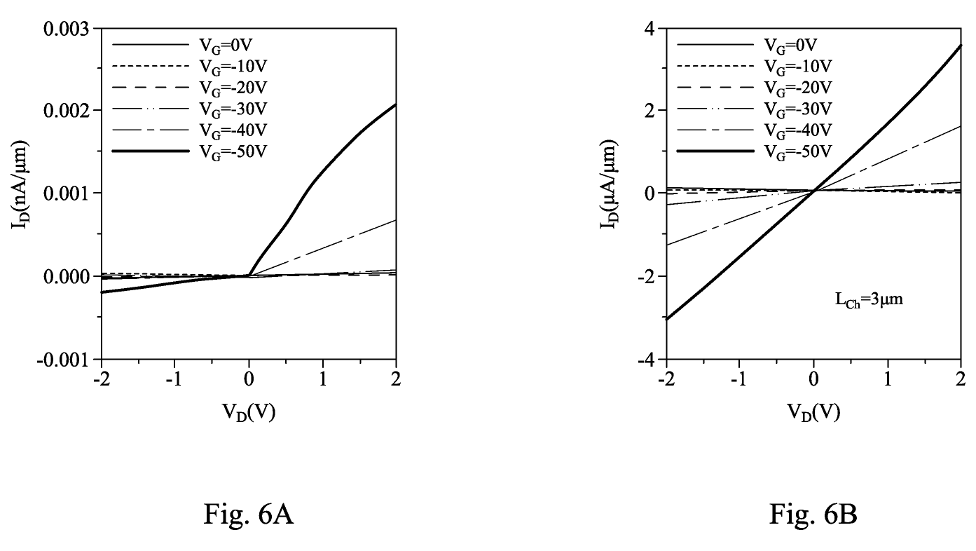

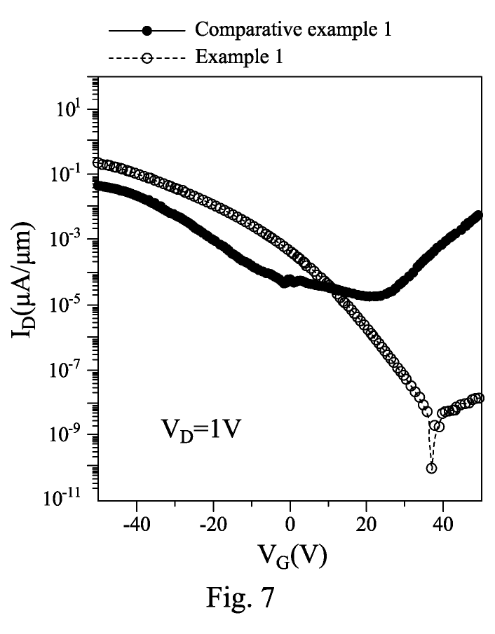

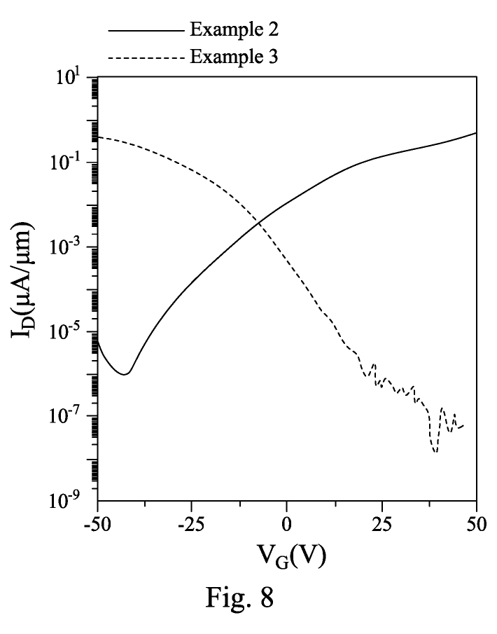

Reference is made to FIG. 6A to FIG. 8, FIG. 6A is an I_{D}-V_{D} diagram of Comparative example 1, FIG. 6B is an I_{D}-V_{D} diagram of Example 1, FIG. 7 is an I_{D}-V_{G} diagram of Example 1 and Comparative example 1, and FIG. 8 is an I_{D}-V_{G} diagram of Example 2 and Example 3. In FIG. 6A, when the voltage V_{D} is greater than 0, the drain current I_{D} generated in Comparative example 1 is positive. When the voltage V_{D} is less than 0, the drain current I_{D} generated in Comparative example 1 is almost 0. In FIG. 6B, when the voltage V_{D} is greater than 0, the drain current I_{D} generated in Example 1 is positive. When the voltage V_{D} is less than 0, the drain current I_{D} generated in Example 1 is negative. In Example 1, the linear relationship between the drain current I_{D} and the voltage V_{D} is good when the voltage V_{D} is greater than 0 or the voltage V_{D} is less than 0 in Example 1. In detail, when Example 1 is used as a FET, the FET can stably generate current under positive voltage or negative voltage, and can have good FET performance. In FIG. 6A and FIG. 6B, Comparative example 1 is compared with Example 1, and the current generated in Example 1 is 1000 times than the current generated in Comparative example 1. Therefore, the semiconductor material prepared by the method for preparing the semiconductor material of the present disclosure is beneficial to amplify the current signals and to have a better controllability. In FIG. 7 and FIG. 8, Comparative example 1 is compared with Example 1, Example 2 and Example 3, the applying voltages V_{G} of Example 1 and Example 2 are more positive than Comparative example 1, and the applying voltage V_{G} of Example 3 is more negative than Comparative example 1. For example, in Example 1, the first chalcogenide material is tungsten diselenide, and the second chalcogenide material is vanadium diselenide, so that a hole-type semiconductor is successfully obtained. It can be demonstrated that the properties of the semiconductor material can be adjusted by adjusting the doping area formed with the first chalcogenide material and the second chalcogenide material.

### Hysteresis Analysis

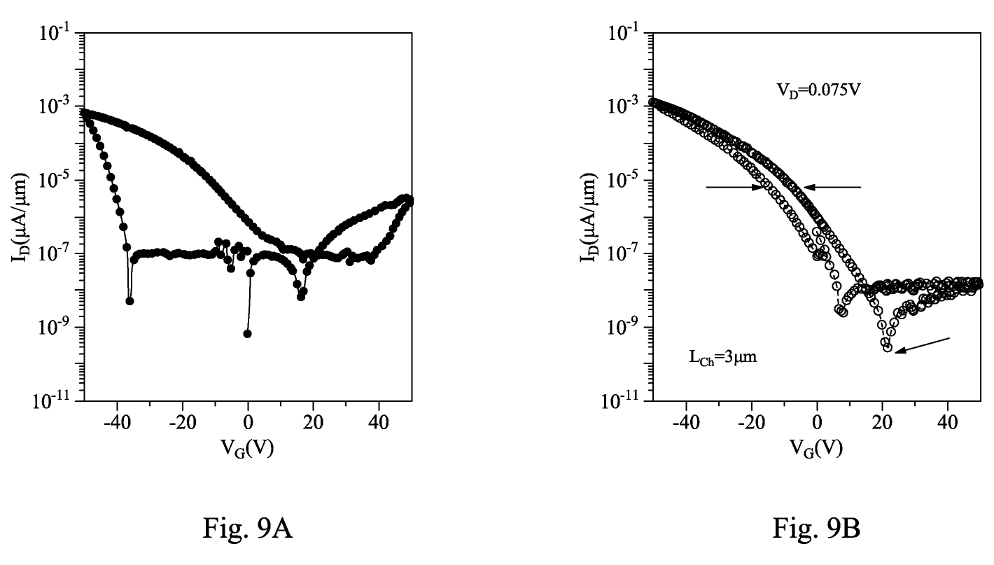

Reference is made to FIG. 9A to FIG. 9B, FIG. 9A is a hysteresis analysis of Comparative example 1, and FIG. 9B is a hysteresis analysis of Example 1. During the testing of the hysteresis analysis, the electrical consistency and the reaction efficiency of the semiconductor material can be confirmed via the scanning with the cyclic voltage range. The cyclic voltage range starts from a starting voltage, the scanning is performed towards the positive voltage till 45 V, the scanning is performed towards the negative voltage till -45 V, the scanning is performed towards the starting voltage 0 V, and the hysteresis analysis is completed. In the hysteresis analysis, there are two drain currents I_{D} under the same voltage, one of the drain currents is generated on the scanning path towards the positive voltage, and the other of the drain currents is generated on the scanning path towards the negative voltage. When the values of the drain currents are closer, and the electrical consistency and the reaction efficiency of the semiconductor material is better. The reason for influencing the hysteresis analysis is the charge trap caused by the structure defect in the semiconductor material. Conversely, when the values of the drain currents I_{D} are closer, the hysteresis is less obvious, so that it can be demonstrated that the higher structure integrity of the semiconductor material can avoid the charge trap, and it is favorable for the electrical consistency and the reaction efficiency of the semiconductor material. In FIG. 9A and FIG. 9B, Comparative example 1 is compared with Example 1, the values of the drain currents I_{D} under the same voltage are closer in Example 1, which means that the hysteresis is smaller in Example 1, and it is demonstrated that the structure integrity of the semiconductor material prepared by the method for preparing the semiconductor material of the present disclosure is better.

In conclusion, in the method for preparing the semiconductor material of the present disclosure, the first chalcogenide units and the second chalcogenide units are formed by controlling the first frequency and the second frequency of the power source, and the first chalcogenide units and the second chalcogenide units are deposited to form the base layer and the doping area so as to obtain the semiconductor material. The range and the size of the doping area can be adjusted by disposing the masking layer during depositing. Therefore, the semiconductor material with high performance and precise dimension is obtained. In the method for preparing the semiconductor material of the present disclosure, the ablating level can be controlled precisely to form the first chalcogenide units and the second chalcogenide units, and the lattice structure would not be damaged during depositing, so that the semiconductor material with the structural integrity can be obtained, and it is favorable for the electrical consistency and the reaction efficiency of the semiconductor material. Moreover, the electron-type semiconductor material or the hole-type semiconductor material can be formed by selecting the first chalcogenide material and the second chalcogenide material according to the requirement. Therefore, the process can be adjusted flexibly to control properties of the semiconductor material, and it is favorable for the mass-production and the industrial application of the semiconductor material so as to ensure the quality of the semiconductor material.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A method for preparing a semiconductor material, comprising:
ablating a first chalcogenide material by a power source at a first frequency to form a plurality of first chalcogenide units;
depositing the first chalcogenide units on a substrate to form a base layer;
forming at least one masking layer on the base layer, wherein a portion of a surface of the base layer is exposed outside the at least one masking layer;
ablating a second chalcogenide material by the power source at a second frequency to form a plurality of second chalcogenide units;
depositing the second chalcogenide units on the portion of the surface of the base layer to form at least one doping area; and
removing the at least one masking layer to obtain the semiconductor material.

2. The method for preparing the semiconductor material of claim 1, wherein the at least one masking layer comprises a resin and a photosensitizer.

3. The method for preparing the semiconductor material of claim 1, wherein the power source is a laser source, and a wavelength of the laser source is 100 nm to 850 nm.

4. The method of claim 1, wherein the power source comprises at least one selected from the group consisting of a laser source, a charged-particle source, a neutral-particle source and a broadband photon source.

5. The method for preparing the semiconductor material of claim 1, wherein the power source is a pulsed laser or a continuous-wave laser.

6. The method for preparing the semiconductor material of claim 5, wherein the power source is the pulsed laser, and a repetition rate of the pulsed laser is 0.01 Hz to 100 MHz.

7. The method for preparing the semiconductor material of claim 1, wherein a heating temperature provided on the portion of the surface of the base layer is 200^{o}C to 330^{o}C during depositing the second chalcogenide units on the portion of the surface of the base layer.

8. The method for preparing the semiconductor material of claim 7, wherein the heating temperature provided on the portion of the surface of the base layer is 250^{o}C to 300^{o}C.

9. The method for preparing the semiconductor material of claim 1, wherein a chalcogenide source of the first chalcogenide material is sulfur, selenium or tellurium, and a chalcogenide source of the second chalcogenide material is sulfur, selenium or tellurium.

10. The method for preparing the semiconductor material of claim 9, wherein the first chalcogenide material comprises a group IIIB element, a group IVB element, a group VB element, a group VIB element, a group VIIB element, a group VIIIB element, a group IB element, a group IIB element or a group VA element of Periodic Table.

11. The method for preparing the semiconductor material of claim 9, wherein the second chalcogenide material comprises a group IIIB element, a group IVB element, a group VB element, a group VIB element, a group VIIB element, a group VIIIB element, a group IB element, a group IIB element or a group VA element of Periodic Table.

12. The method for preparing the semiconductor material of claim 1, wherein a thickness of the substrate is 30 nm to 200 nm.

13. A semiconductor material, prepared by the method for preparing the semiconductor material of claim 1, and comprising:
the base layer comprising the first chalcogenide units; and
the at least one doping area comprising the second chalcogenide units, wherein the second chalcogenide units are bonded to the first chalcogenide units of the base layer.

14. The semiconductor material of claim 13, wherein the first chalcogenide material comprises a group VIB element of Periodic Table, the second chalcogenide material comprises a group IIIB element, a group IVB element or a group VB element of Periodic Table, and the semiconductor material comprises at least one p-type semiconductor portion.

15. The semiconductor material of claim 13, wherein the first chalcogenide material comprises a group VIB element of Periodic Table, the second chalcogenide material comprises a group VIIB element, a group VIIIB element, a group IB element, a group IIB element or a group VA element of Periodic Table, and the semiconductor material comprises at least one n-type semiconductor portion.

16. The semiconductor material of claim 13, wherein the first chalcogenide material comprises a group VB element of Periodic Table, the second chalcogenide material comprises a group IIIB element or a group IVB element of Periodic Table, and the semiconductor material comprises at least one p-type semiconductor portion.

17. The semiconductor material of claim 13, wherein the first chalcogenide material comprises a group VB element of Periodic Table, the second chalcogenide material comprises a group VIB element, a group VIIB element, a group VIIIB element, a group IB element, a group IIB element or a group VA element of Periodic Table, and the semiconductor material comprises at least one n-type semiconductor portion.

18. The semiconductor material of claim 13, further comprising at least one covering layer covering the base layer, wherein the at least one covering layer comprises a plurality of third chalcogenide units, each of the third chalcogenide units comprises a third chalcogenide material, and the third chalcogenide units are bonded to the first chalcogenide units of the base layer.

19. The semiconductor material of claim 18, wherein the first chalcogenide material comprises a group VIB element of Periodic Table, the second chalcogenide material comprises a group IIIB element, a group IVB element or a group VB element of Periodic Table, the third chalcogenide material comprises a group VIIB element, a group VIIIB element, a group IB element, a group IIB element or a group VA element of Periodic Table, and the semiconductor material comprises at least one p-type semiconductor portion and at least one n-type semiconductor portion.

20. The semiconductor material of claim 18, wherein the first chalcogenide material comprises a group VB element of Periodic Table, the second chalcogenide material comprises a group IIIB element or a group IVB element of Periodic Table, the third chalcogenide material comprises a group VIB element, a group VIIB element, a group VIIIB element, a group IB element, a group IIB element or a group VA element of Periodic Table, and the semiconductor material comprises at least one p-type semiconductor portion and at least one n-type semiconductor portion.
